(19) United States
(12) Patent Application Publication
(10) Pub. No.: US 2026/0136479 A1
(43) Pub. Date: May 14, 2026

(54) POWER SUPPLY DEVICE

(71) Applicant: Chengli LI, Suzhou (CN)

(72) Inventors: Huan LIU, Suzhou (CN); Junwu ZHOU, Suzhou (CN)

(73) Assignee: Chengli LI, Suzhou (CN)

(21) Appl. No.: 19/011,401

(22) Filed: Jan. 6, 2025

(30) Foreign Application Priority Data
Nov. 12, 2024 (CN) 202422748456.8

(51) Int. Cl. H05K 5/02

(52) U.S. Cl. CPC H05K 5/0217

(57) ABSTRACT

A power supply device includes a housing, a high-power supply module, a low-power supply module, and an insulating member. The high-power supply module is arranged in a first cavity in the housing, and is used to output a high-power voltage, and its power input comes from an alternating current source. The low-power supply module is arranged in a second cavity in the housing, and is used to output a low-power voltage, and its power input comes from a direct current source. The insulating member in the housing insulates and isolates the high-power supply module from the low-power supply module. The insulating member increases the creepage distance between the high-power supply module and the low-power supply module, so that the actual distance between the high-power supply module and the low-power supply module can be reduced as much as possible while considering electrical safety.

### BACKGROUND OF THE INVENTION

The present invention relates to the electrical field, and in particular, to a power supply device.

Conventionally, high-power sockets and low-power sockets that provide power output to users in RVs are installed separately. High-power sockets are used to provide AC voltage to high-power electrical appliances in RVs, including, for example, two-hole sockets, three-hole sockets, etc. Low-power sockets are used to provide DC voltage to small electronic devices (for example, mobile phones, tablet computers, smart watches, etc.), which can be, for example, various types of USB interfaces, etc. The power input of the high-power socket is usually derived from an external AC power supply or a vehicle-mounted generator, and the power input of the low-power socket is usually derived from a vehicle-mounted energy storage battery. RV manufacturers need to purchase these two types of socket products separately and open two mounting holes on the mounting wall of the RV for installation. This will take up the already limited space on the RV and increase the manufacturing cost. For RV users, the two separately installed sockets lack simplicity and aesthetics.

### SUMMARY OF THE INVENTION

In order to solve the problems of the power socket in the conventional art, embodiments of the present invention provide a power supply device.

A first aspect of the present disclosure is a power supply device, which includes a housing, a high-power supply module, a low-power supply module, and an insulating member. A first cavity and a second cavity are provided inside the housing. The high-power supply module is provided in the first cavity, and is used to output a high-power voltage, and the power input of the high-power supply module comes from an alternating current source. The low-power supply module is provided in the second cavity, and is used to output a low-power voltage, and the power input of the low-power supply module comes from a direct current source. An insulating member is provided in the housing, and the insulating member insulates and isolates the high-power supply module from the low-power supply module.

In this embodiment, the provision of the insulating member increases the creepage distance between the high-power supply module and the low-power supply module, thereby reducing the actual distance required between the high-power supply module and the low-power supply module. The power supply device of this embodiment can provide high-power voltage and low-power voltage at the same time, and the device itself occupies a smaller space and is more streamlines and aesthetic.

In one embodiment, the insulating member is disposed between the first cavity and the second cavity to insulate and isolate the high-power supply module from the low-power supply module.

In one embodiment, the insulating member divides the interior of the housing into the first cavity and the second cavity.

In one embodiment, the insulating member includes a first insulating member, and the first insulating member is disposed on an inner wall of the first cavity.

In one embodiment, the insulating member includes a second insulating member, and the second insulating member is disposed on an inner wall of the second cavity.

In one embodiment, the insulating member is formed integrally with the housing.

In one embodiment, the insulating member is detachably disposed in the housing.

In one embodiment, the insulating member is detachably disposed at different positions in the housing to change the shapes of the first cavity and the second cavity.

In one embodiment, at least one of the high-power supply module and the low-power supply module is arranged in the corresponding cavity by fastener connection, welding, bonding, riveting or clamping.

In one embodiment, the height of the insulating member inside the housing is greater than the height of the low-power supply module in the second cavity.

In one embodiment, the power supply device further includes a cover affixed to the housing, to cover the first cavity and the second cavity.

In one embodiment, the power supply device further includes a faceplate affixed to the housing, which includes an opening to expose the high-power supply interface of the high-power supply module and the low-power supply interface of the low-power supply module.

In one embodiment, the power supply device is adapted to be mounted in a mounting hole on the mounting interface.

In a second aspect, embodiments of the present invention provide a power supply device, which includes a housing, a high-power supply module, and a low-power supply module. The housing has a first frame and a second frame. The high-power supply module is affixed to the first frame for outputting a high-power voltage, and the power input of the high-power supply module is provided by an alternating current source. The low-power supply module is affixed to the second frame for outputting a low-power voltage, and the power input of the low-power supply module is provided by a direct current source. The outer surface of the high-power supply module and/or the outer surface of the low-power supply module is provided with an insulating material, and the insulating material insulates and isolates the high-power supply module from the low-power supply module.

In this embodiment, by providing an insulating material on the outer surface of at least one of the high-power supply module and the low-power supply module, the high-power supply module is electrically insulated from the low-power supply module, which ensures the electrical safety inside the power supply device. The inputs of the high-power supply module and the low-power supply module are provided by external power sources respectively, so the internal circuit of the power supply device is simplified and the occupied space can be reduced accordingly.

In one embodiment, the high-power supply module is detachably affixed to the first frame, and the low-power supply module is detachably affixed to the second frame.

In one embodiment, the power supply device further comprises a faceplate affixed to the housing, which comprises an opening to expose the high-power supply interface of the high-power supply module and the low-power supply interface of the low-power supply module.

In one embodiment, the power supply device is adapted to be mounted in a mounting hole on a mounting interface.

### BRIEF DESCRIPTION OF DRAWINGS

Preferred embodiments of the present invention are described with reference to the drawings. These drawings explain the embodiments and their operating principle, and only illustrate structures that are necessary to the understanding of the invention. These drawings are not to scale. In the drawings, like features are designated by like reference symbols.

FIG. 1 is an exploded view of a power supply device according to a first embodiment of the present invention.

FIG. 2 illustrates the housing of the power supply device of the first embodiment.

FIG. 3 illustrates an exemplary insulating member of the power supply device of the first embodiment.

FIG. 4 illustrates another exemplary insulating member of the power supply device of the first embodiment.

FIG. 5 illustrates internal structures of the power supply device of the first embodiment.

FIG. 6 is another illustration of the power supply device of the first embodiment, where the components within the housing have been assembled.

FIG. 7 is an exploded view of a power supply device according to a second embodiment of the present invention.

FIG. 8 illustrates the power supply of the second embodiment after partial assembly.

FIG. 9 is another illustration of the power supply device of the second embodiment, where the components within the housing have been assembled.

### DETAILED DESCRIPTION OF THE INVENTION

Preferred embodiments of the present invention are described below with reference to the drawings. These drawings and descriptions explain embodiments of the invention but do not limit the invention. The described embodiments are not all possible embodiments of the present invention. Other embodiments are possible without departing from the spirit and scope of the invention, and the structure and/or logic of the illustrated embodiments may be modified. Thus, it is intended that the scope of the invention is defined by the appended claims. In the following descriptions, directional terms such as up, down, left, right, front, rear, etc. are relative terms with reference to the orientation of the drawing figures; these terms are used for better understanding of the invention, but they do not limit the scope of the invention.

Before describing the embodiments, some terms used in this disclosure are defined here to help the reader better understand this disclosure.

In this disclosure, terms such as “connect”, “couple”, “link” etc. should be understood broadly, without limitation to physical connection or mechanical connection, but can include electrical connection, and can include direct or indirection connections. Terms such as “a” and “one” do not limit the quantity, and refers to “at least one”.

In the descriptions below, terms such as “including” are intended to be open-ended and mean “including without limitation”, and can include other contents. “Based on” means “at least partly based on.” “An embodiment” means “at least one embodiment.” “Another embodiment” means “at least another embodiment,” etc. In this disclosure, the above terms do not necessarily refer to the same embodiments. Further, the various features, structures, materials or characteristics may be suitably combined in any of the one or more embodiments. Those of ordinary skill in the art may combine the various embodiments and various characteristics of the embodiments described herein when they are not contrary to each other.

Compared with conventional technologies, embodiments of the present invention provide a power supply device which includes a high-power supply module (or module group) and a low-power supply module (or module group) insulated and isolated from each other, configured to provide a high-power voltage and a low-power voltage to various electrical equipment respectively. Various embodiments of the power supply device will be described below.

### First Embodiment

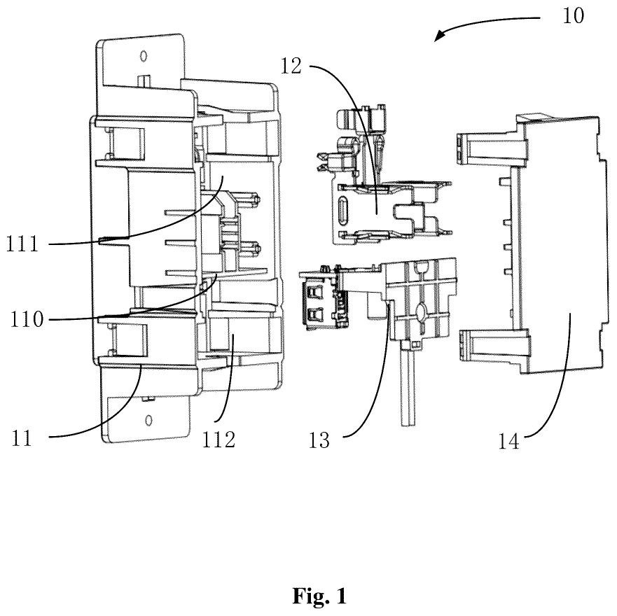

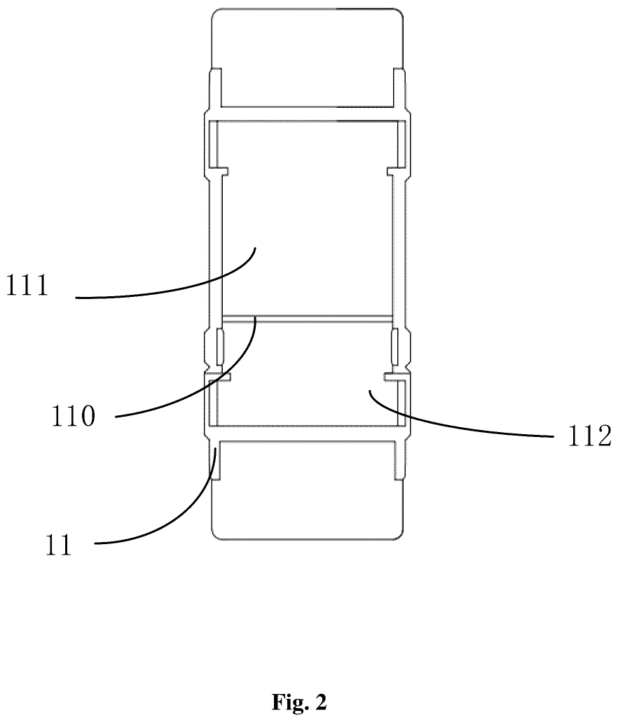

FIG. 1 is an exploded view of a power supply device according to a first embodiment of the present invention. The power supply device 10 includes a housing 11, a high-power supply module 12, a low-power supply module 13, and an insulating member 110. FIG. 2 illustrates the housing of the power supply device of the first embodiment. A first cavity 111 and a second cavity 112 are formed inside the housing 11. The high-power supply module 12 is arranged in the first cavity 111 for outputting a high-power voltage. A high-power supply interface such as a two-hole type or a three-hole type socket may be provided on one side surface of the high-power supply module 12, which can receive a plug of a high-power electrical appliance, to output an AC voltage of, for example, 125 volts or 250 volts. The power input of the high-power supply module 12 is from an AC power, for example, from an external mains or a vehicle-mounted generator. The low-power supply module 13 is arranged in the second cavity 112 for outputting a low-power voltage. A low-power supply interface such as a USB interface may be provided on one side surface of the low-power supply module 13, for example, including but not limited to a USB-A interface, a USB-C interface, etc. The low-power supply interface can receive cables for charging electronic devices (such as mobile phones, tablet computers, smart watches, etc.), to output a DC voltage such as 5 volts to 36 volts. Most commonly, the low-power supply interface outputs a DC voltage of about 5 volts, which is useful for charging personal consumer electronic devices. The power input of the low-power supply module 13 is from a direct current source, which can be derived from an on-board energy storage battery. It should be noted that the terms “high-power supply” and “low-power supply” in this disclosure may generally refer to high-current and low-current, and/or high-voltage and low-voltage, and/or high-power and low-power; i.e., generally speaking, the two power supplies supply different current and/or voltage and/or power. The insulating member 110 is disposed in the housing 11, which insulates and isolates the high-power supply module 12 and the low-power supply module 13.

The insulating member 110 is disposed between the first cavity 111 and the second cavity 112 to insulate and isolate the high-power supply module 12 and the low-power supply module 13. In the illustrated example of FIG. 2, the insulating member 110 divides the interior of the housing 11 into the first cavity 111 and the second cavity 112.

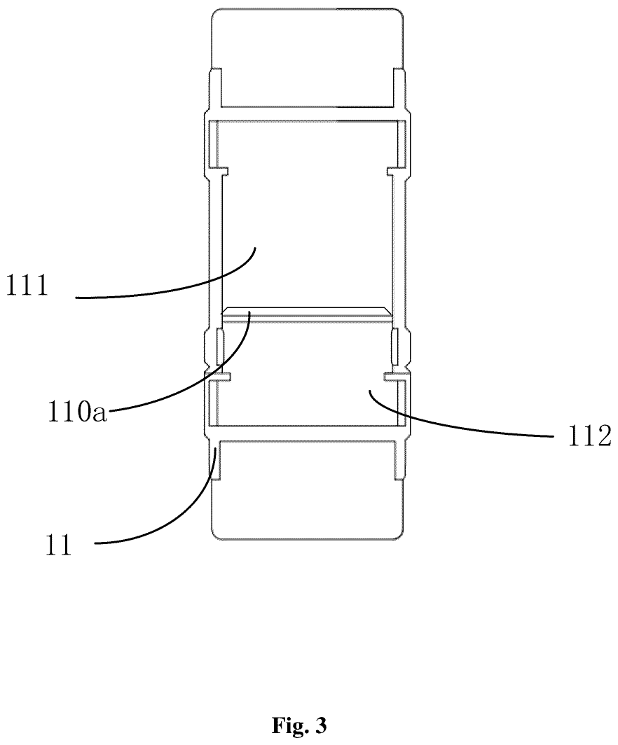

FIG. 3 illustrates an exemplary insulating member of the power supply device of the first embodiment. In this example, the insulating member 110 includes a first insulating member 110a, which is disposed on the inner wall of the first cavity 111.

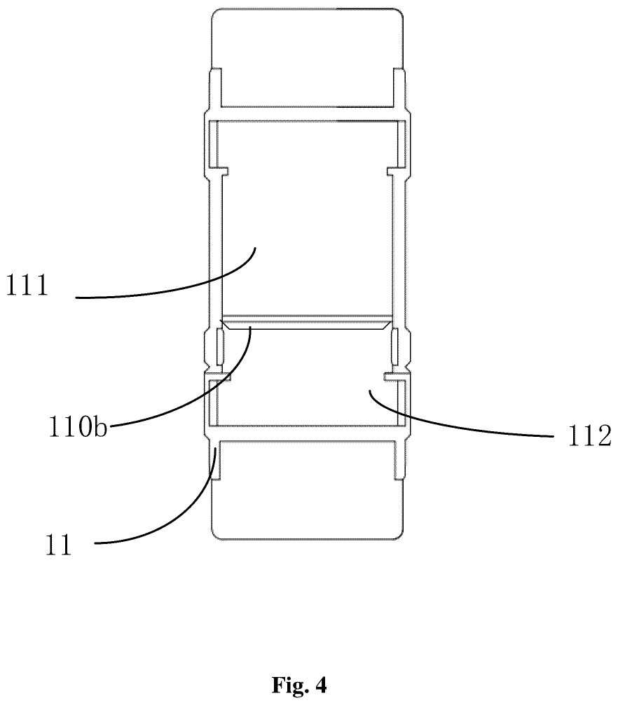

FIG. 4 illustrates another exemplary insulating member of the power supply device of the first embodiment. In this example, the insulating member 110 includes a second insulating member 110b, which is disposed on the inner wall of the second cavity 112.

The insulating member 110 may include plastic, rubber, ceramic, or other electrically insulating materials. In other examples, both the first insulating member 110a and the second insulating member 110b are provided, disposed on the inner wall of the first cavity 111 and the inner wall of the second cavity 112, respectively, where the first insulating member 110a and the second insulating member 110b may be the same or different materials.

In one example, the insulating member 110 may be formed integrally with the housing 11. In another example, the insulating member 110 may be a separate component that is detachably disposed in the housing 11. The insulating member 110 may be detachably disposed at different positions in the housing 11 to change the shapes of the first cavity 111 and the second cavity 112, for example, so as to be flexibly applicable to different arrangements of the high-power supply module and the low-power supply module.

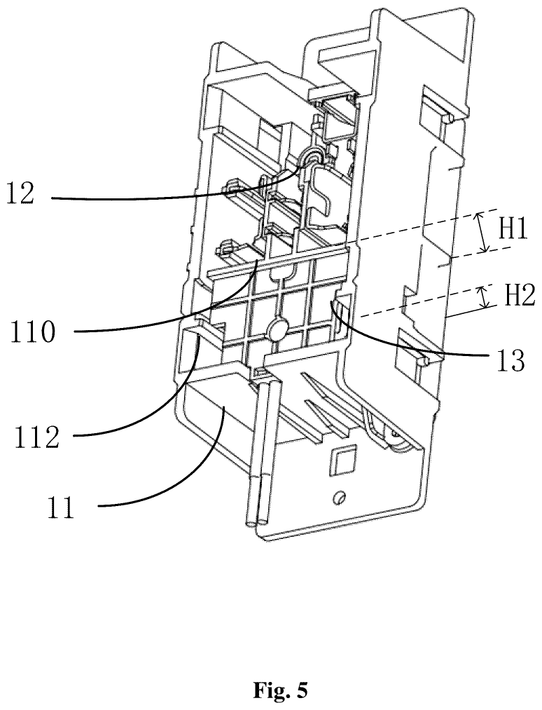

FIG. 5 illustrates internal structures of the power supply device of the first embodiment. The high-power supply module 12 and the low-power supply module 13 are arranged in corresponding cavities, and affixing to the housing by a suitable means, including without limitation, fastener connection, welding, adhesive bonding, riveting, clamping, etc. Optionally, the height H1 of the insulating member 110 inside the housing 11 is greater than the height H2 of the low-power supply module 13 in the second cavity 112. An advantage of such a structure is that the electrical clearance and creepage distance between the high-power supply module 12 and the low-power supply module 13 are increased.

Referring to FIG. 1, the power supply device 10 further includes a cover 14 affixed to the housing 11, configured to cover the first cavity 111 and the second cavity 112. The cable or cables that couple the power supply device 10 to the external direct current or alternating current sources may pass through the surface of the cover 14, or through a gap between the cover 14 and the housing 11.

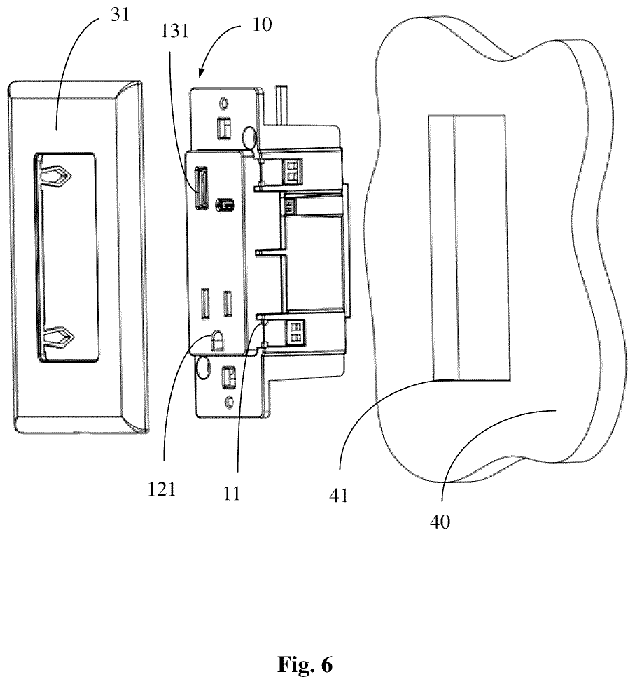

FIG. 6 is another illustration of the power supply device of the first embodiment, where the components within the housing have been assembled. As shown in FIG. 6, the power supply device 10 further includes a faceplate 31 affixed to the housing 11, which includes an opening to expose the high-power supply interface 121 of the high-power supply module 12 and the low-power supply interface 131 of the low-power supply module 13. After the power supply device 10 is assembled, it is suitable for being installed in a mounting hole 41 on the mounting interface 40 (such as a wall panel, etc.).

In this embodiment, the insulating member 110 in the power supply device 10 electrically insulates the high-power supply module 12 and the low-power supply module 13. The provision of the insulating member 110 increases the creepage distance between the high-power supply module 12 and the low-power supply module 13, so that the actual distance between the high-power supply module 12 and the low-power supply module 13 can be reduced as much as possible in consideration of electrical safety. This technical solution reduces the space occupied by the power supply device 10, which is particularly necessary in the application scenario of RVs. In addition, since the power inputs of the high-power supply module 12 and the low-power supply module 13 come from external AC power and external DC power, no additional voltage conversion circuit (such as an AC voltage to DC voltage converter) is required inside the power supply device 10, so the power supply device 10 is relatively small in size.

Of course, the power supply device 10 of this embodiment can be applied to RVs, and can also be applied to other applicable scenarios such as homes and office environments.

### Second Embodiment

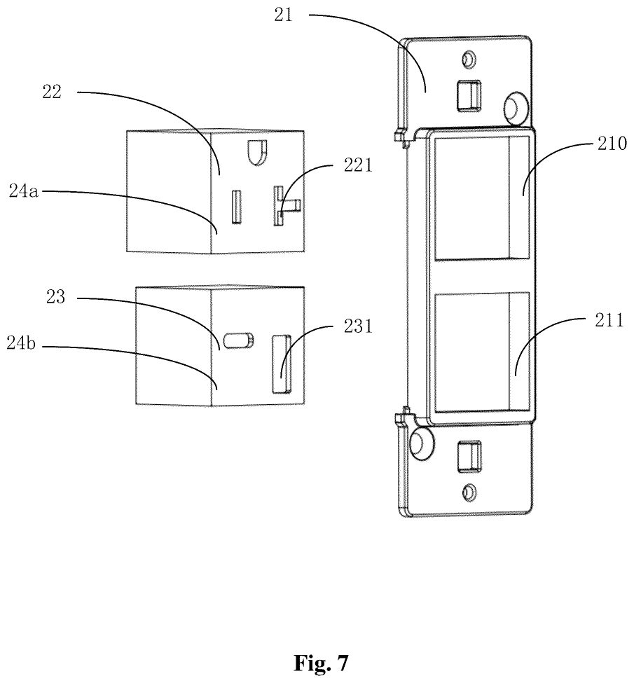

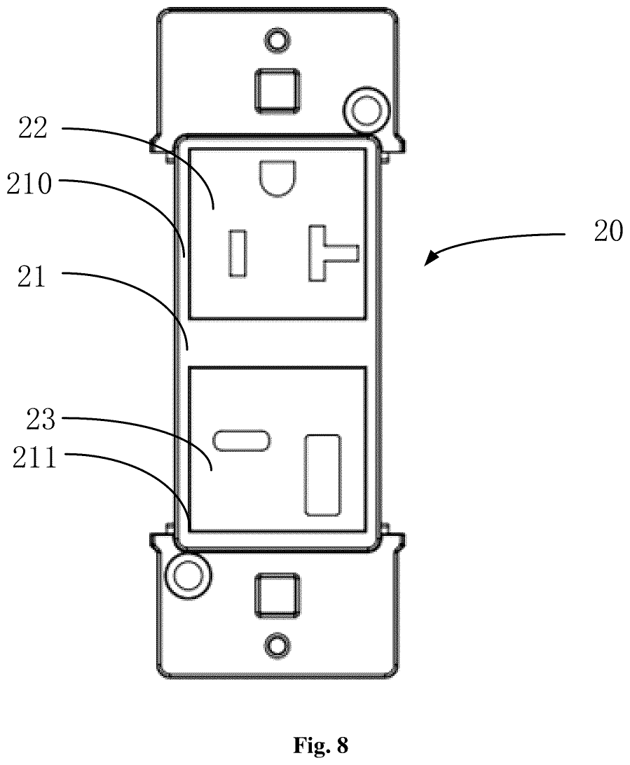

FIG. 7 is an exploded view of a power supply device according to a second embodiment of the present invention. FIG. 8 illustrates the power supply of the second embodiment after partial assembly. The power supply device 20 includes a housing 21, a high-power supply module 22, and a low-power supply module 23. The housing 21 includes a first frame 210 and a second frame 211. The high-power supply module 22 is affixed to the first frame 210 for outputting a high-power voltage. A high-power supply interface 221 such as a two-hole type or a three-hole type socket may be provided on one side surface of the high-power supply module 22, and the high-power supply interface 221 may be configured to receive a plug of a high-power electrical appliance, to output an AC voltage of, for example, 125 volts or 250 volts. The power input of the high-power supply module 22 is from an AC power source, for example, from an external mains supply or a vehicle-mounted generator. The low-power supply module 23 is affixed to the second frame 211 for outputting a low-power voltage. A low-power supply interface 231 such as a USB type may be provided on one side surface of the low-power supply module 23, including without limitation, a USB-A interface, a USB-C interface, etc. The low-power supply interface 231 is configured to receive cables for charging electronic devices (such as mobile phones, tablet computers, smart watches, etc.), and output a DC voltage such as 5 volts to 36 volts. Most commonly, the low-power supply interface 231 outputs a DC voltage of about 5 volts, which is useful for charging personal consumer electronic devices. The power input of the low-power supply module 23 is from a direct current source, which can be derived from an on-board energy storage battery. The outer surface of the high-power supply module 22 and/or the outer surface of the low-power supply module 23 is provided with an insulating material, which insulates and isolates the high-power supply module 22 from the low-power supply module 23.

The insulating material may be, for example, plastic, inorganic insulating material, organic insulating material, or mixed insulating material. Referring to FIG. 7, in this embodiment, the outer surface of the high-power module 22 is provided with a first insulating material 24a and the outer surface of the low-power module 23 is provided with a second insulating material 24b, and the insulating materials 24a and 24b on the outer surfaces of the modules enclose electrical circuits therein. The first insulating material 24a and the second insulating material 24b may be the same or different materials. The shape of the housing 21 is not limited to the example of FIG. 7 which has only a frame structure; it may also be similar to the example shown in FIG. 1 which has a housing with cavities. In another example, the outer surface of the high-power module 22 is provided with an insulating material 24a, but the outer surface of the low-power module 23 is not provided with an insulating material 24b. The low-power module 23 is assembled into the housing, and its electrical insulation from the outside is achieved by the insulating material of the housing. In another example, the outer surface of the low-power module 23 is provided with an insulating material 24b, but the outer surface of the high-power module 22 is not provided with an insulating material 24a. The high-power module 22 is assembled into the housing and is electrically insulated from the outside by the insulating material of the housing.

The high-power supply module 22, au be detachably affixed to the first frame 210, and the low-power supply module 23 may be detachably affixed to the second frame 211. The fixing methods include, without limitation, fastener connection, welding, bonding, riveting, or clamping, etc.

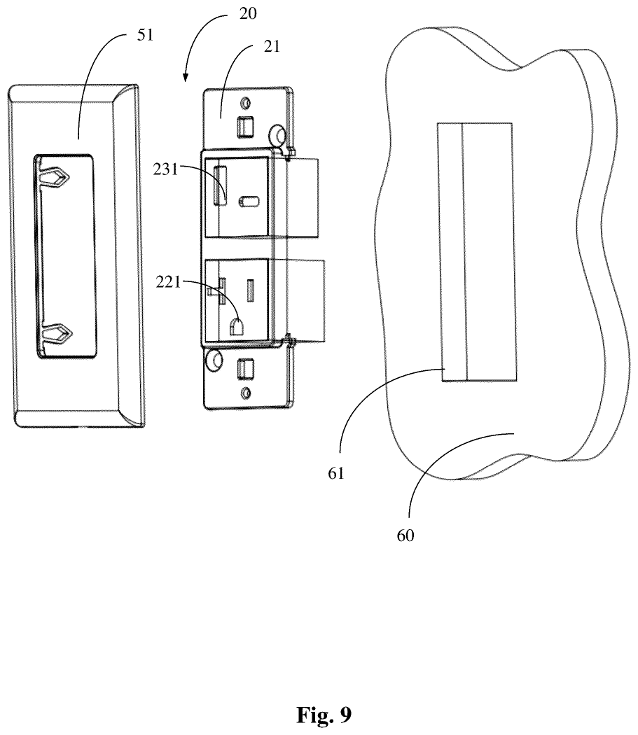

FIG. 9 is another illustration of the power supply device of the second embodiment, where the components within the housing have been assembled. Referring to FIG. 9, the power supply device 20 further includes a faceplate 51 affixed to the housing 21, which includes an opening to expose a high-power supply interface 221 of the high-power supply module 22 and a low-power supply interface 231 of the low-power supply module 23. After the power supply device 20 is assembled, it is suitable for being installed in a mounting hole 61 on a mounting interface 60 (such as a wall panel, etc.).

In this embodiment, insulating material is provided on the outer surface of at least one of the high-power supply module 22 and the low-power supply module 23, so that the high-power supply module 22 and the low-power supply module 23 are electrically insulated from each other. The provision of insulating material ensures the electrical safety in the power supply device 20, increases the creepage distance between the high-power supply module 22 and the low-power supply module 23, and prevents short circuit. In addition, because the power inputs of the high-power supply module 22 and the low-power supply module 23 are from external AC power and external DC power, the power supply device 20 does not require additional space to accommodate the voltage conversion circuit (such as an AC voltage to DC voltage converter). The power supply device 20 has a relatively small volume which is advantageous in application scenario of RVs.

Of course, the power supply device 20 of this embodiment can be applied to RVs, and can also be applied to other applicable scenarios such as homes and office environments.

While the present invention is described above using specific examples, these examples are only illustrative and do not limit the scope of the invention. It will be apparent to those skilled in the art that various modifications, additions and deletions can be made to the power supply device of the present invention without departing from the spirit or scope of the invention.

1. A power supply device, comprising:
a housing, defining a first cavity and a second cavity in an interior of the housing;
a high-power supply module, disposed in the first cavity, having a power input coupled to an alternating current source, and configured to output a high-power voltage;
a low-power supply module, disposed in the second cavity, having a power input coupled to a direct current source, and configured to output a low-power voltage; and
an insulating member, disposed in the housing, configured to insulate and isolate the high-power supply module and the low-power supply module from each other.

2. The power supply device of claim 1, wherein the insulating member is disposed between the first cavity and the second cavity to insulate and isolate the high-power supply module and the low-power supply module from each other.

3. The power supply device of claim 2, wherein the insulating member divides the interior of the housing into the first cavity and the second cavity.

4. The power supply device of claim 1, wherein the insulating member includes a first insulating member disposed on an inner wall of the first cavity.

5. The power supply device of claim 1, wherein the insulating member includes a second insulating member disposed on an inner wall of the second cavity.

6. The power supply device of claim 1, wherein the insulating member is formed integrally with the housing.

7. The power supply device of claim 1, wherein the insulating member is detachably disposed in the housing.

8. The power supply device of claim 7, wherein the insulating member is configured to be detachably disposed at different positions in the housing to change shapes of the first cavity and the second cavity.

9. The power supply device of claim 1, wherein at least one of the high-power supply module and the low-power supply module is affixed in the corresponding cavity by fastener connections, welding, bonding, riveting or clamping.

10. The power supply device of claim 1, wherein a height of the insulating member inside the housing is greater than a height of the low-power supply module in the second cavity.

11. The power supply device of claim 1, further comprising a cover affixed to the housing, configured to cover the first cavity and the second cavity.

12. The power supply device of claim 1, further comprising a faceplate affixed to the housing, which includes an opening to expose a high-power supply interface of the high-power supply module and a low-power supply interface of the low-power supply module.

13. The power supply device of claim 1, wherein the power supply device is adapted to be mounted in a mounting hole on the mounting interface.

14. A power supply device, comprising:
a housing, including a first frame and a second frame;
a high-power supply module, affixed to the first frame, having a power input coupled to an alternating current source, and configured to output a high-power voltage; and
a low-power supply module, affixed to the second frame, having a power input coupled to a direct current source, and configured to output a low-power voltage,
wherein an outer surface of the high-power supply module and/or an outer surface of the low-power supply module includes an insulating material configured to insulate and isolate the high-power supply module and the low-power supply module from each other.

15. The power supply device of claim 14, wherein the high-power supply module is detachably affixed to the first frame, and the low-power supply module is detachably affixed to the second frame.

16. The power supply device of claim 14, further comprising a faceplate affixed to the housing, including an opening to expose a high-power supply interface of the high-power supply module and a low-power supply interface of the low-power supply module.

17. The power supply device of claim 14, wherein the power supply device is adapted to be mounted in a mounting hole on a mounting interface.
